(19) United States
(12) Patent Application Publication
(10) Pub. No.: US 2016/0135333 A1
(43) Pub. Date: May 12, 2016

(54) SYSTEMS AND METHODS FOR ECONOMICAL AIRFLOW SENSOR AND CLOSED-LOOP AIRFLOW CONTROL IN AN INFORMATION HANDLING SYSTEM

(71) Applicant: Dell Products L.P., Round Rock, TX (US)

(72) Inventors: Dominick A. Lovicott, Round Rock, TX (US); Robert B. Curtis, Georgetown, TX (US)

(21) Appl. No.: 14/534,449

(22) Filed: Nov. 6, 2014

(51) Int. Cl. H05K 7/20

(52) U.S. Cl. CPC H05K 7/20718; H05K 7/20836

(57) ABSTRACT

In accordance with embodiments of the present disclosure, an air mover control system may include a first input configured to receive a first temperature signal from a first temperature sensor, a second input configured to receive a second temperature signal from a second temperature sensor, and logic. The logic may be configured to determine an estimated airflow based on the first temperature signal and the second temperature signal, determine an error based on a target airflow setpoint and the estimated airflow, and control a velocity of an air mover based on the error.

### TECHNICAL FIELD

The present disclosure relates in general to information handling systems, and more particularly to an economical airflow sensor and a closed-loop airflow control utilizing such airflow sensor in an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Thermal control of an information handling system may utilize two methodologies to maintain safe and efficient operation: open-loop control and closed-loop control. Closed-loop control typically employs thermal sensor information in a feedback loop that targets a desired operating point by manipulating air mover speeds and/or throttling (e.g., reducing the power requirements of) information handling resources based on the thermal sensor information. However, many information handling resources lack thermal sensors and thus may be thermally managed by applying open-loop control based on a hardware configuration of an information handling system (e.g., as determined from information in a basic input/output system or “BIOS”) of the information handling system. In open-loop control, thermal requirements for different hardware configurations are met by defining air mover speed curves and/or lookup tables for the specific hardware configuration that define a target air mover speed or target airflow rate for such configuration.

Despite many advantages of open-loop control, it has many drawbacks. For example, open-loop control settings must often be based on “worst-case” conditions and are not suited to unexpected changes. For example, thermal conditions may change such that characterized air mover speed and/or airflow set points are rendered ineffective such as in the case of airflow blockage, external air pressure interactions, non-uniform system inlet temperatures, and/or other reasons.

Another drawback may be present in modular-type systems, such as a shared infrastructure system which includes slots for accepting different types of modular information handling systems (e.g., blades) and modular information handling resources, is that airflow variations may exist across different chassis and slots. However, open-loop control may be defined for the lowest airflow slot and may not compensate when more airflow is available in other slots. One solution to this problem is defining hardware airflow impedances and estimating airflow based on an understanding of air mover performance and hardware depopulation. However, such a solution may require an immense amount of system characterization due to the large number of possible hardware permutations and will be prone to error such that taking advantage of improved airflow conditions may not be fully realized.

Furthermore, when hardware is leveraged into a new shared infrastructure environment, open-loop configuration settings must often be re-characterized and new open-loop control settings must be defined. Such retuning consumes significant time and resources.

### SUMMARY

In accordance with the teachings of the present disclosure, the disadvantages and problems associated with airflow control in a temperature control system may be substantially reduced or eliminated.

In accordance with embodiments of the present disclosure, an air mover control system may include a first input configured to receive a first temperature signal from a first temperature sensor, a second input configured to receive a second temperature signal from a second temperature sensor, and logic. The logic may be configured to determine an estimated airflow based on the first temperature signal and the second temperature signal, determine an error based on a target airflow setpoint and the estimated airflow, and control a velocity of an air mover based on the error.

In accordance with these and other embodiments of the present disclosure, a method may include receiving a first temperature signal from a first temperature sensor. The method may also include receiving a second temperature signal from a second temperature sensor. The method may further include determining an estimated airflow based on the first temperature signal and the second temperature signal. The method may additionally include determining an error based on a target airflow setpoint and the estimated airflow. The method may also include controlling a velocity of the air mover based on the error.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2 illustrates a graph depicting example characterization data of an unheated temperature sensor and a heated temperature sensor in the example information handling system illustrated in FIG. 1 versus airflow in the example information handling system, in accordance with embodiments of the present disclosure;

FIG. 3 illustrates a block diagram depicting an example control loop using an unheated temperature sensor and a heated temperature sensor in the example information handling system illustrated in FIG. 1, in accordance with embodiments of the present disclosure; and

FIG. 4 illustrates a flow chart of an example method for closed loop airflow control in an information handling system, in accordance with embodiments of the present disclosure.

### DETAILED DESCRIPTION

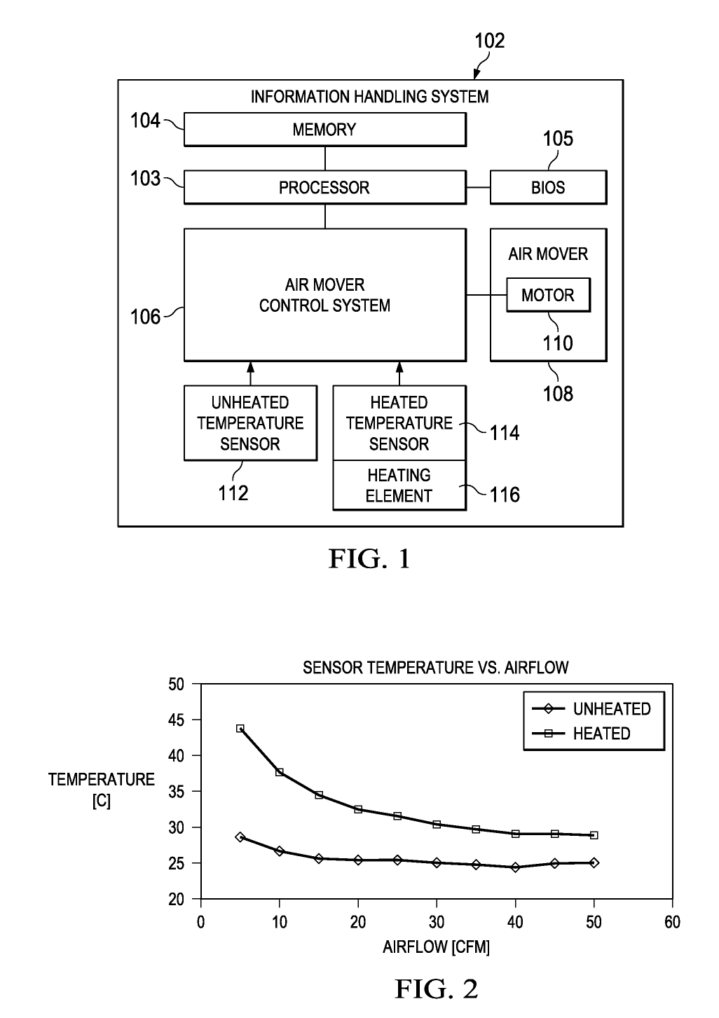

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104, a BIOS 105, an air mover control system 106, an air mover 108, an unheated temperature sensor 112, a heated temperature sensor 114, and a heating element 116.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102. Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

A BIOS 105 may include any system, device, or apparatus configured to identify, test, and/or initialize information handling resources of information handling system 102, and/or initialize interoperation of information handling system 102 with other information handling systems. “BIOS” may broadly refer to any system, device, or apparatus configured to perform such functionality, including without limitation, a Unified Extensible Firmware Interface (UEFI). In some embodiments, BIOS 105 may be implemented as a program of instructions that may be read by and executed on processor 103 to carry out the functionality of BIOS 105. In these and other embodiments, BIOS 105 may comprise boot firmware configured to be the first code executed by processor 103 when information handling system 102 is booted and/or powered on. As part of its initialization functionality, code for BIOS 105 may be configured to set components of information handling system 102 into a known state, so that one or more applications (e.g., an operating system or other application programs) stored on compatible media (e.g., disk drives) may be executed by processor 103 and given control of information handling system 102. In some embodiments, BIOS 105 may also be configured to store and/or report configuration information regarding a hardware configuration (e.g., population of various information handling resources) of information handling system 102.

Air mover control system 106 may be communicatively coupled to processor 103 and may include any system, device, or apparatus configured to receive one or more signals indicative of one or more temperatures within information handling system 102 (e.g., one or more signals from one or more temperature sensors 112), and based on such signals, calculate an air mover driving signal to maintain an appropriate level of cooling, increase cooling, or decrease cooling, as appropriate, and communicate such air mover driving signal to air mover 108. Example functionality of air mover control system 106 is set forth in greater detail below.

Air mover 108 may be communicatively coupled to air mover control system 106, and may include any mechanical or electro-mechanical system, apparatus, or device operable to move air and/or other gasses. In some embodiments, air mover 108 may comprise a fan (e.g., a rotating arrangement of vanes or blades which act on the air). In other embodiments, air mover 108 may comprise a blower (e.g., centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by the air mover control signal communicated from air mover control system 106. In operation, air mover 108 may cool information handling resources of information handling system 102 by drawing cool air into an enclosure housing the information handling resources from outside the chassis, expel warm air from inside the enclosure to the outside of such enclosure, and/or move air across one or more heatsinks (not explicitly shown) internal to the enclosure to cool one or more information handling resources.

Unheated temperature sensor 112 may be any system, device, or apparatus (e.g., a thermometer, thermistor, etc.) configured to communicate a signal to air mover control system 106 indicative of a temperature within information handling system 102. While this disclosure refers to this component as “unheated,” unheated temperature sensor 112 may in fact be heated by ambient air and/or air internal to information handling system 102. The term “unheated” is intended to indicate that unheated temperature sensor 112 is not actively heated by a heating element specifically intended to heat unheated temperature sensor 112 (e.g., not thermally coupled to a heating element such as heating element 116 described below).

Heated temperature sensor 114 may be any system, device, or apparatus (e.g., a thermometer, thermistor, etc.)

configured to communicate a signal to air mover control system 106 indicative of a temperature within information handling system 102. Heated temperature sensor 114 may also include or may be thermally coupled to a heating element 116 (e.g., heating element 116 may be integral to or integrated with heated temperature sensor 114 and/or may be separate from but thermally coupled to heated temperature sensor 114). Heating element 116 may comprise any system, device, or apparatus for generating heat and communicating such generated heat to heated temperature sensor 114. For example, heating element 116 may comprise programmable heating elements (e.g., electrically resistive loads) under the control of air mover control system 106, processor 103, or another information handling resource of information handling system 102. In some embodiments, such control may be implemented in order to heat heating element 116 to a predetermined known or desired temperature. To communicate heat generated by heating element 116 to heated temperature sensor 114, one or more heat pipes, heat spreaders, or other thermally-conductive components coupling heat temperature sensor 114 to heating element 116 may be employed.

For ease of exposition, FIG. 1 depicts only one each of air mover control system 106, air mover 108, unheated temperature sensor 112, and heated temperature sensor 114. However, it is noted that information handling system 102 may include two or more air movers 108 and each such air mover 108 may have a dedicated respective air mover control system 106. It is further noted that an air mover control system 106 may receive temperature signals from one or more unheated temperature sensors 112 and/or one or more heated temperature sensors 114, and that a single unheated temperature sensor 112 and/or a single heated temperature sensor may communicate temperature signals to one or more air mover control systems 106.

In addition to processor 103, memory 104, BIOS 105, air mover control system 106, air mover 108, unheated temperature sensor 112, heated temperature sensor 114, and heating element 116, information handling system 102 may include one or more other information handling resources.

In operation, information handling system 102 may be configured such that unheated temperature sensor 112 monitors an ambient inlet air temperature while heated temperature sensor 114 is heated with a known or predetermined power level and is responsive to airflow at a point within an enclosure of information handling system 102. As airflow varies in information handling system 102, the monitored temperature of unheated temperature sensor 112 may remain predominantly stable while the monitored temperature of heated temperature sensor 114 may vary. Air mover control system 106 may then estimate airflow based on the monitored temperatures of unheated temperature sensor 112 and heated temperature sensor 114. For example, during characterization and testing of information handling system 102, testing may be performed to characterize the temperatures of unheated temperature sensor 112 and heated temperature sensor 114 as a function of airflow. FIG. 2 illustrates a graph depicting example characterization data of unheated temperature sensor 112 and heated temperature sensor 114, in accordance with embodiments of the present disclosure. Accordingly, during operation, air mover control system 106 may correlate the monitored temperatures of unheated temperature sensor 112 and heated temperature sensor 114 to the characterization data collected during testing in order to estimate airflow.

Air mover control system 106 may also use the airflow estimate as an input to a closed loop air mover control to correct for an error between the airflow estimate and a target airflow, wherein the target airflow may be based on open-loop cooling requirements of information handling system 102 which may, in some embodiments, be dependent upon a hardware configuration of information handling system 102.

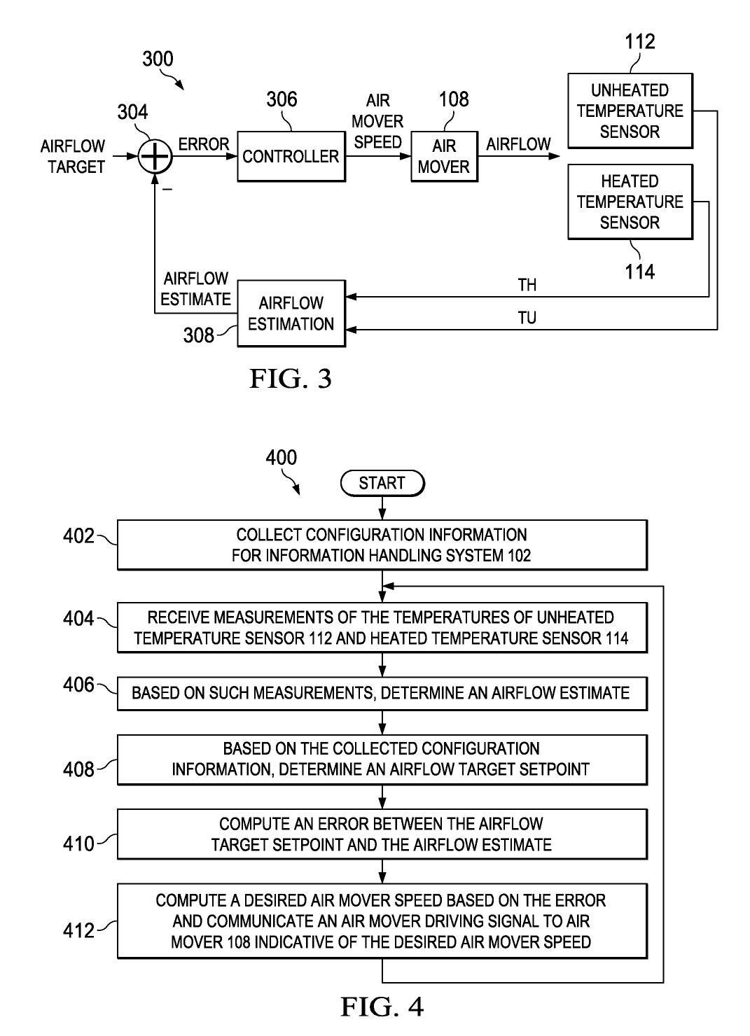

FIG. 3 illustrates a block diagram depicting an example control loop 300 using unheated temperature sensor 112 and heated temperature sensor 114, in accordance with embodiments of the present disclosure. As shown in FIG. 3, example control loop 300 may include a summer 304, a controller 306, air mover 108, unheated temperature sensor 112, heated temperature sensor 114, and an airflow estimation 308. In some embodiments, portions of example control loop 300 may be implemented by air mover control system 106. For example, in such embodiments, summer 304, controller 306, and airflow estimation 308 may be implemented by air mover control system 106.

Summer 304 may comprise any system, device, or apparatus for calculating an error between an airflow target setpoint and an airflow estimate based on temperatures sensed by unheated temperature sensor 112 and heated temperature sensor 114. The airflow target setpoint may be based on open-loop cooling requirements of information handling system 102 which may, in some embodiments, be dependent upon a hardware configuration of information handling system 102.

Controller 306 may comprise any system, device, or apparatus configured to, based on the error calculated by summer 304, generate an air mover driving signal indicative of a desired speed for air mover 108. In some embodiments, the air mover driving signal may comprise a pulse-width modulation (PWM) signal, in which the width of a pulse of a periodic square wave signal may be indicative of a desired operating velocity for air mover 108. In these and other embodiments, controller 306 may be implemented using a proportional-integral-differential (PID) controller.

Air mover 108 may operate at a speed which is a function of the air mover driving signal, and based on the speed of air mover 108 and airflow impedance of the airflow path of air driven by air mover 108, air mover 108 may generate an airflow. Such airflow may provide cooling proximate to each of unheated temperature sensor 112 and heated temperature sensor 114 such that they measure temperatures of T_{U} and T_{H}, respectively.

Based on temperatures T_{U} and T_{H}, airflow estimation 308 may generate an airflow estimate. As described above, such airflow estimate may be based on characterization data characterizing the temperatures of unheated temperature sensor 112 and heated temperature sensor 114 as a function of airflow. In some embodiments, such characterization data may be stored (e.g., as a map, list, table, array, or other suitable data structure) in computer-readable media integral to or accessible to air mover control system 106.

FIG. 4 illustrates a flow chart of an example method 400 for closed loop airflow control in an information handling system, in accordance with embodiments of the present disclosure. According to one or more embodiments, method 400 may begin at step 402. As noted above, teachings of the present disclosure may be implemented in a variety of configurations of information handling system 102. As such, the preferred initialization point for method 400 and the order of the steps comprising method 400 may depend on the implementation chosen.

At step 402, air mover control system 106 may collect configuration information for information handling system 102 from BIOS 105. At step 404, air mover control system 106 may receive measurements of the temperatures of unheated temperature sensor 112 and heated temperature sensor 114. At step 406, based on such measurements, air mover control system 106 (e.g., airflow estimation 308) may determine an airflow estimate.

At step 408, based on the collected configuration information from BIOS 105, air mover control system 106 may determine an airflow target setpoint. At step 410, air mover control system 106 (e.g., summer 304) may compute an error between the airflow target setpoint and the airflow estimate. At step 412, air mover control system 106 (e.g., controller 306) may compute a desired air mover speed based on the error and communicate an air mover driving signal to air mover 108 indicative of the desired air mover speed, and air mover 108 may operate in accordance with the air mover driving signal. After completion of step 412, method 400 may proceed again to step 404.

Although FIG. 4 discloses a particular number of steps to be taken with respect to method 400, method 400 may be executed with greater or fewer steps than those depicted in FIG. 4. In addition, although FIG. 4 discloses a certain order of steps to be taken with respect to method 400, the steps comprising method 400 may be completed in any suitable order.

Method 400 may be implemented using information handling system 102 or any other system operable to implement method 400. In certain embodiments, method 400 may be implemented partially or fully in software and/or firmware embodied in computer-readable media and executable on a processor or controller of information handling system 102.

Although the foregoing discussion contemplates application systems and methods for closed-loop control to operation of an air mover, similar methods and systems may be generalized and applied to other closed loop controls.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. An air mover control system comprising:
a first input configured to receive a first temperature signal from a first temperature sensor;
a second input configured to receive a second temperature signal from a second temperature sensor; and
logic configured to:
determine an estimated airflow based on the first temperature signal and the second temperature signal;
determine an error based on a target airflow setpoint and the estimated airflow; and
control a velocity of an air mover based on the error.

2. The air mover control system of claim 1, wherein the first temperature sensor comprises an unheated temperature sensor.

3. The air mover control system of claim 1, wherein the first temperature sensor senses an inlet ambient air temperature of an information handling system.

4. The air mover control system of claim 1, wherein the second temperature sensor comprises a heated temperature sensor.

5. The air mover control system of claim 1, wherein the second temperature sensor senses a temperature internal to an enclosure of an information handling system.

6. An information handling system comprising:
an air mover; and
an air mover control system communicatively coupled to the air mover and configured to:
receive a first temperature signal from a first temperature sensor;
receive a second temperature signal from a second temperature sensor; and
determine an estimated airflow based on the first temperature signal and the second temperature signal;
determine an error based on a target airflow setpoint and the estimated airflow; and
control a velocity of the air mover based on the error.

7. The information handling system of claim 6, wherein the first temperature sensor comprises an unheated temperature sensor.

8. The information handling system of claim 6, wherein the first temperature sensor senses an inlet ambient air temperature of the information handling system.

9. The information handling system of claim 6, wherein the second temperature sensor comprises a heated temperature sensor.

10. The information handling system of claim 6, wherein the second temperature sensor senses a temperature internal to an enclosure of the information handling system.

11. A method comprising:
receiving a first temperature signal from a first temperature sensor;
receiving a second temperature signal from a second temperature sensor;
determining an estimated airflow based on the first temperature signal and the second temperature signal;
determining an error based on a target airflow setpoint and the estimated airflow; and
controlling a velocity of the air mover based on the error.

12. The method of claim 11, wherein the first temperature sensor comprises an unheated temperature sensor.

13. The method of claim 11, wherein the first temperature sensor senses an inlet ambient air temperature of an information handling system.

14. The method of claim 11, wherein the second temperature sensor comprises a heated temperature sensor.

15. The method of claim 11, wherein the second temperature sensor senses a temperature internal to an enclosure of an information handling system.
